(19) United States
(12) Patent Application Publication
(10) Pub. No.: US 2026/0213116 A1
(43) Pub. Date: Jul. 23, 2026

(54) Ion Beam Adjustment Method and Ion Beam Device

(71) Applicant: Hitachi High-Tech Corporation, Minato-ku, Tokyo (JP)

(72) Inventors: Naoko HIROSE, Tokyo (JP); Yasuhiko SUGIYAMA, Tokyo (JP); Hiroshi OBA, Tokyo (JP)

(21) Appl. No.: 19/143,052

(22) PCT Filed: Jan. 23, 2023
(86) PCT No.: PCT/JP2023/001908

§ 371 Date: Jun. 25, 2025

(51) Int. Cl. H01J 37/09; H01J 37/20; H01J 37/30; H01J 37/317

(52) U.S. Cl. CPC H01J 37/09; H01J 37/20; H01J 37/3007; H01J 37/317; H01J 2237/0458; H01J 2237/1501

(57) ABSTRACT

A linear edge of an aperture of a movable diaphragm is caused to be perpendicular to an optical axis of an ion beam. An ion beam adjustment method is a method for adjusting an ion beam emitted to a sample via a movable diaphragm having an aperture with at least one linear edge. The method includes irradiating the sample with an ion beam having a first focal point and an ion beam having a second focal point different from the first focal point (S207), and adjusting a position of the aperture of the movable diaphragm based on a positional relation between a first side corresponding to the linear edge of a first irradiation mark on the sample, which is formed by the ion beam having the first focal point, and a second side corresponding to the linear edge of a second irradiation mark on the sample, which is formed by the ion beam having the second focal point (S209).

### TECHNICAL FIELD

The present invention relates to an ion beam adjustment method and an ion beam device.

### BACKGROUND ART

The performance of a focused ion beam device used for device analysis and material analysis of a semiconductor is improved by improving performance of an electrostatic lens and shortening an operation distance of a beam, but these improvements reach limits thereof. However, with miniaturization of semiconductor devices after introduction of extreme ultraviolet lithography (EUVL) in particular, a further improvement in the performance of a focused ion beam device is required in a sample preparation step for a transmission electron microscope (TEM) used in analysis, and specifically, processing with less edge sagging is required.

Therefore, a method for reducing sagging of a processing edge by using a condition in which a linear edge of an aperture and an optical axis of a beam are perpendicular to each other or a condition in which a rectangular aperture or the like is decentered in combination with defocusing (for example, see PTL 1 and PTL 2) has been known. It is also known that a method for adjusting an optical system can be performed based on an irradiation mark (see, for example, PTL 3 and PTL 4).

### CITATION LIST

### Patent Literature

PTL 1: JP3531323B
PTL 2: JP5048919B
PTL 3: JP5044813B
PTL 4: U.S. Pat. No. 8,124,932B

### SUMMARY OF INVENTION

### Technical Problem

However, it is not easy to visually check the aperture of the movable diaphragm disposed in the column and the optical axis of the beam, and therefore, the positions of the optical axis of the beam and the aperture are not clear. Therefore, it is not easy for an engineer having an advanced technique to adjust a linear edge of the aperture to be perpendicular to the optical axis of the beam.

Further, although it is known that the optical system can be adjusted based on the irradiation mark of the beam, PTL 3 provides a normal optical axis adjustment method which is not an adjustment method for aligning one side of the aperture with the optical axis of the beam.

Therefore, an object of the present disclosure is to provide an ion beam adjustment method and an ion beam device capable of making a straight line of an aperture of a movable diaphragm and an optical axis of an ion beam perpendicular to each other.

### Solution to Problem

An ion beam adjustment method according to the disclosure is a method for adjusting an ion beam emitted to a sample via a movable diaphragm having an aperture with at least one linear edge. The method includes: irradiating the sample with an ion beam having a first focal point and an ion beam having a second focal point different from the first focal point; and adjusting a position of the aperture of the movable diaphragm based on a positional relation between a first side corresponding to the linear edge of a first irradiation mark formed by the ion beam having the first focal point and a second side corresponding to the linear edge of a second irradiation mark formed by the ion beam having the second focal point.

### Advantageous Effects of Invention

According to the ion beam adjustment method of the present disclosure, it is possible to make the linear edge of the aperture of the movable diaphragm and the optical axis of the ion beam perpendicular to each other by adjusting the position of the aperture of the movable diaphragm based on the positional relation between the first side of the first irradiation mark and the second side of the second irradiation mark on the sample.

Other technical problems and novel features will become apparent from description of the present description and the accompanying drawings.

### BRIEF DESCRIPTION OF DRAWINGS

FIG. 1A is an overall schematic diagram of an ion beam device according to Embodiment 1.

FIG. 1B is a hardware block diagram of a control unit according to Embodiment 1.

FIG. 2 is a schematic diagram of a movable diaphragm according to Embodiment 1.

FIG. 3 is a flowchart showing an ion beam adjustment method according to Embodiment 1.

FIG. 4 is a diagram showing states before and after movement of an aperture of the movable diaphragm according to Embodiment 1.

FIG. 5 is a diagram showing an optical path of ion beams according to Embodiment 1.

FIG. 6 is a diagram showing irradiation marks of a hyper-focused ion beam and an under-focused ion beam according to Embodiment 1.

FIG. 7 is a diagram showing a plurality of linear edges of an aperture and a processing surface of a sample according to Embodiment 1.

FIG. 8 is a flowchart showing an ion beam adjustment method according to Embodiment 2.

FIG. 9 is a plan view showing a first example of results of spot irradiation according to Embodiment 2.

FIG. 10 is a plan view showing a second example of the results of spot irradiation according to Embodiment 2.

FIG. 11 is a plan view showing a positional relation between an irradiation mark and each of irradiation positions of a hyper-focused ion beam and an under-focused ion beam according to Embodiment 3.

FIG. 12 is a flowchart showing an ion beam adjustment method according to Embodiment 4.

FIG. 13 is a plan view showing a first example of a scanning irradiation result according to Embodiment 4.

FIG. 14 is a plan view showing a second example of the scanning irradiation result according to Embodiment 4.

FIG. 15 is a plan view showing a third example of the scanning irradiation result according to Embodiment 4.

### DESCRIPTION OF EMBODIMENTS

In the following embodiments, for the sake of convenience, the description may be made by being divided into a plurality of sections or embodiments, but unless otherwise stated, they are not unrelated to one another, and one has a relation with all or a part of modifications, details, supplementary explanations, and the like of the other.

In the following embodiments, when referring to the number of elements (including the number, a numerical value, an amount, a range, or the like) or the like, the number of elements is not limited to a specific number, and may be the specific number or more or the specific number or less, unless otherwise specified or except a case where the number is apparently limited to a specific number in principle.

Further, in the following embodiments, it is needless to mention that components (also including element steps and the like) are not necessarily essential unless otherwise specified or unless clearly considered to be essential in principle.

Similarly, in the following embodiments, when referring to a shape, a positional relation, or the like of a component or the like, the shape or the like is substantially approximate or similar to the shape or the like unless otherwise specified or clearly considered otherwise in principle. The same applies to the above-described numerical value and range.

In all drawings for showing the embodiments, the same members are denoted by the same reference numerals in principle, and repeated description thereof will be omitted.

Hereinafter, embodiments will be described with reference to the drawings.

### Embodiment 1

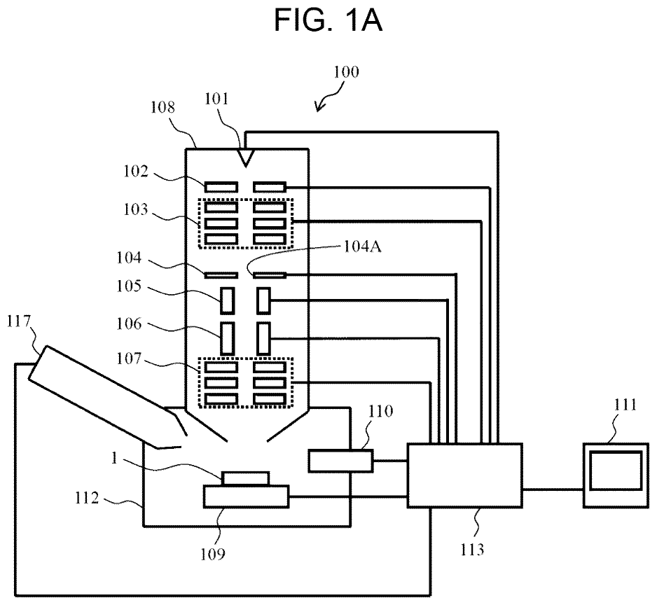

Hereinafter, Embodiment 1 will be described with reference to FIG. 1A to FIG. 7.

### (Ion Beam Device 100)

FIG. 1A is an overall schematic view of an ion beam device 100 according to Embodiment 1. A focused ion beam (FIB) device 100 according to Embodiment 1 is a device that emits a focused ion beam to a sample 1 and performs processing and observation. The ion beam device 100 shown in FIG. 1A includes an ion beam column 108. The ion beam column 108 includes an ion source 101, an extraction electrode 102 that extracts an ion beam from the ion source 101, a focusing lens electrode 103 that focuses the ion beam, a movable diaphragm 104 that changes a beam current and a beam diameter by shielding a part of the ion beam, an Aligner and Stigma electrode 105 that corrects an optical path of the ion beam such that the optical path passes through a center of an objective lens electrode 107, and corrects astigmatism of the ion beam, a deflector 106 that scans the sample 1 with the ion beam, and the objective lens electrode 107 that focuses the ion beam onto the sample 1.

The ion beam device 100 further includes a stage 109 on which the sample 1 is placed, a secondary particle detector 110 that detects secondary particles generated from the sample 1 by emitting an ion beam to the sample 1, and a display unit 111 that displays an image created based on signals detected by the secondary particle detector 110.

The ion beam device 100 further includes a vacuum chamber 112 that stores the ion beam column 108, the stage 109, and the secondary particle detector 110.

The ion beam device 100 further includes a control unit 113 that controls each part of the ion beam column 108, the stage 109, the secondary particle detector 110, and the display unit 111.

The ion beam device 100 further includes a scanning electron microscope (SEM) column 117 in addition to the ion beam column 108 (FIB column) described above.

The ion beam device 100 can emit the focused ion beam to any position on the sample 1, and can perform processing by spot irradiation and processing and observation by beam scanning.

The control unit 113 performs each process related to the adjustment of an optical axis of the ion beam. Of course, an operator can adjust the optical axis of the ion beam without relying on the control unit 113. The optical axis of the ion beam refers to a traveling direction of an ion beam adjusted by a charged particle optical system of the ion beam device 100.

### (Control Unit 113)

FIG. 1B is a hardware block diagram of the control unit 113 according to Embodiment 1. The control unit 113 includes a processor 150, a main storage unit 151, an auxiliary storage unit 152, and an input and output interface (I/F) 153. The processor 150 is a central processing unit that performs various calculations. The processor 150 is, for example, a central processing unit (CPU), a digital signal processor (DSP), or an application specific integrated circuit (ASIC). The processor 150 loads a program (for example, a program related to an ion beam adjustment method) stored in the auxiliary storage unit 152 in a work area of the main storage unit 151 in an executable manner. The main storage unit 151 stores a program executed by the processor 150, data processed by the processor 150, and the like. The processor 150 executes a program loaded in the main storage unit 151 to execute processing related to the ion beam adjustment method and the like. The main storage unit 151 is, for example, a flash memory and a random access memory (RAM). The auxiliary storage unit 152 stores various programs and various kinds of data. The auxiliary storage unit 152 stores, for example, an operating system (OS), various programs, and various tables. The auxiliary storage unit 152 is, for example, a solid state drive (SSD) device and a hard disk drive (HDD) device. The ion beam column 108, the SEM column 117, the stage 109, the secondary particle detector 110, the display unit 111, input devices such as a keyboard and a mouse (not shown), and the like are communicably connected to the input and output I/F 153. Specifically, the processor 150 receives results of processing by the processor 150, issues a command to a power supply necessary for operating the ion beam column or the SEM column, or a driver for driving a motor or the like, and the power supply and the driver output the command and apply the command to the ion beam column or the SEM column through the input and output I/F 153.

### (Movable Diaphragm 104)

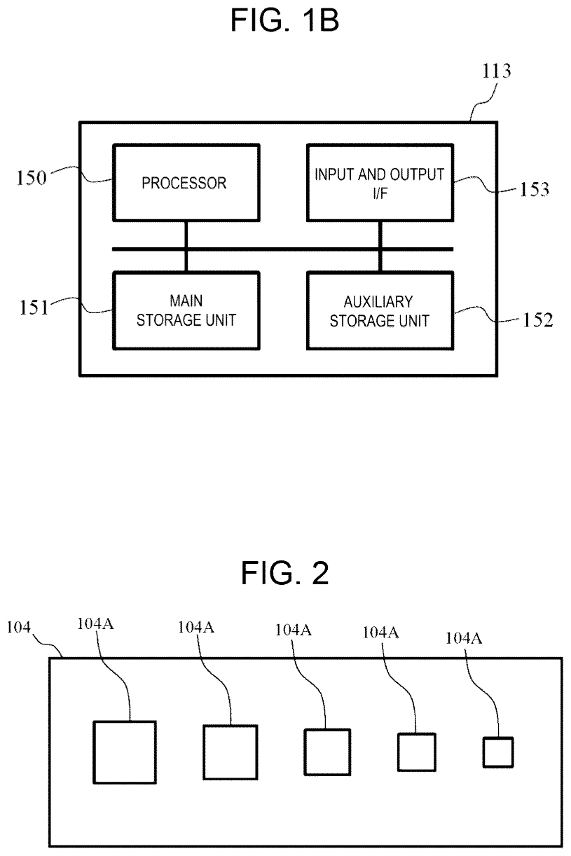

FIG. 2 is a schematic diagram of the movable diaphragm 104 according to Embodiment 1. The movable diaphragm 104 shown in FIG. 2 is viewed from above (ion source 101 side). The movable diaphragm 104 is provided with a plurality of apertures 104A. The number of the apertures 104A provided in the movable diaphragm 104 may be one or more. The movable diaphragm 104 has an aperture 104A with at least one linear edge. The aperture 104A formed in the movable diaphragm 104 according to Embodiment 1 has a substantially square shape with four sides being linear edges. The shape of the aperture 104A may be a shape other than a substantially square as long as at least one side is a linear edge.

### (Ion Beam Adjustment Method)

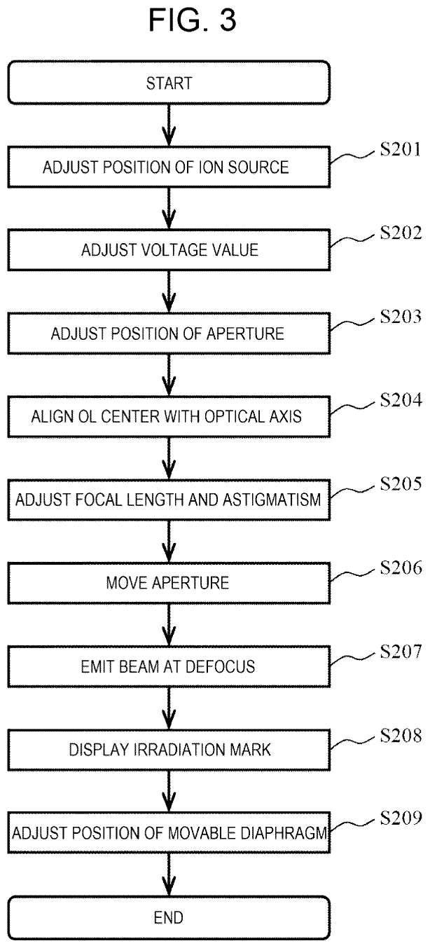

FIG. 3 is a flowchart illustrating the ion beam adjustment method according to Embodiment 1. Next, the ion beam adjustment method according to Embodiment 1 will be described with reference to FIG. 1A to FIG. 6.

The adjustment of the ion beam is performed by a procedure of aligning a center of the aperture 104A of the movable diaphragm 104 with an optical axis of the ion beam, adjusting a shape of the ion beam, then changing a position of the movable diaphragm 104, and making the linear edge of the aperture 104A and the optical axis of the ion beam perpendicular to each other. Each step in FIG. 3 is executed by the control unit 113.

First, the control unit 113 physically moves the ion source 101 and performs adjustment such that a center component of the ion beam emitted from the ion source 101, in other words, a component having a peak intensity passes through a center of the focusing lens electrode 103 that focuses the ion beam (step S201).

Secondly, the control unit 113 changes a voltage value of the focusing lens electrode 103 in order to obtain a target current value (step S202). The current value is monitored by, for example, a Faraday cup.

Thirdly, the control unit 113 performs adjustment such that the ion beam having passed through the center of the focusing lens electrode 103 passes through the center of the aperture 104A of the movable diaphragm 104 (step S203). Examples of the method include a method of moving the movable diaphragm 104 to a position where no image shake is observed in the scanned image by slightly changing an applied voltage applied to the focusing lens electrode 103. However, examples of the method also include a method of moving the movable diaphragm 104 to a position where the current can be maximized by increasing the applied voltage applied to the focusing lens electrode 103 in the case of a condition in which the resolution is poor and the image shake is hardly recognized.

Fourthly, the control unit 113 performs adjustment such that the ion beam having passed through the center of the aperture 104A of the movable diaphragm 104 passes through a center of the objective lens electrode 107 (objective lens (OL) center) (step S204). As a method thereof, a method of adjusting an aligner voltage by slightly changing an applied voltage applied to the objective lens electrode 107 so that no image shake is observed in a scanned image is exemplified.

Fifthly, the control unit 113 adjusts a focal length and astigmatism to adjust the shape of the ion beam (step S205). Examples of the adjustment method include a method of selecting an optimum shape by performing spot irradiation while varying an applied voltage applied to the Aligner and Stigma electrode 105 or the objective lens electrode 107. In addition, a voltage at which an optimum image can be acquired may be set while checking an observation image. Specifically, the method described in PTL 3 (JP5044813) or PTL 4 (U.S. Pat. No. 8,124,932) may be used.

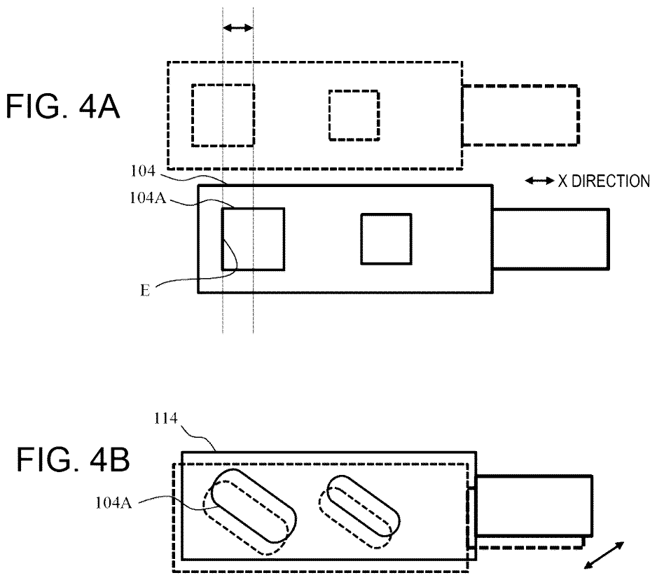

Sixthly, the control unit 113 moves the position of the aperture 104A of the movable diaphragm 104 (step S206). For example, the movable diaphragm 104 whose position can be controlled with an accuracy of 1 μm is moved along a movement direction X by a distance that is half an aperture width of the aperture 104A in the movement direction X as shown in (A) of FIG. 4. The aperture 104A used here is not limited to a quadrangular shape or an oval as long as one side has a linear edge, and may have any shape. The movement amount varies depending on the shape, and the direction of movement also varies with the shape as shown in (B) of FIG. 4. In the example of (A) of FIG. 4, the aperture 104A has a linear edge E.

Seventhly, the control unit 113 irradiates the sample 1 with an ion beam using a defocused beam having a defocusing amount larger than the aberration (step S207). Specifically, the control unit 113 irradiates the sample 1 with an ion beam having a first focal point and an ion beam having a second focal point different from the first focal point. In Embodiment 1, the first focal point is a hyperfocal point or an under-focal point, and the second focal point is an under-focal point if the first focal point is a hyperfocal point, and is a hyperfocal point if the first focal point is an under-focal point.

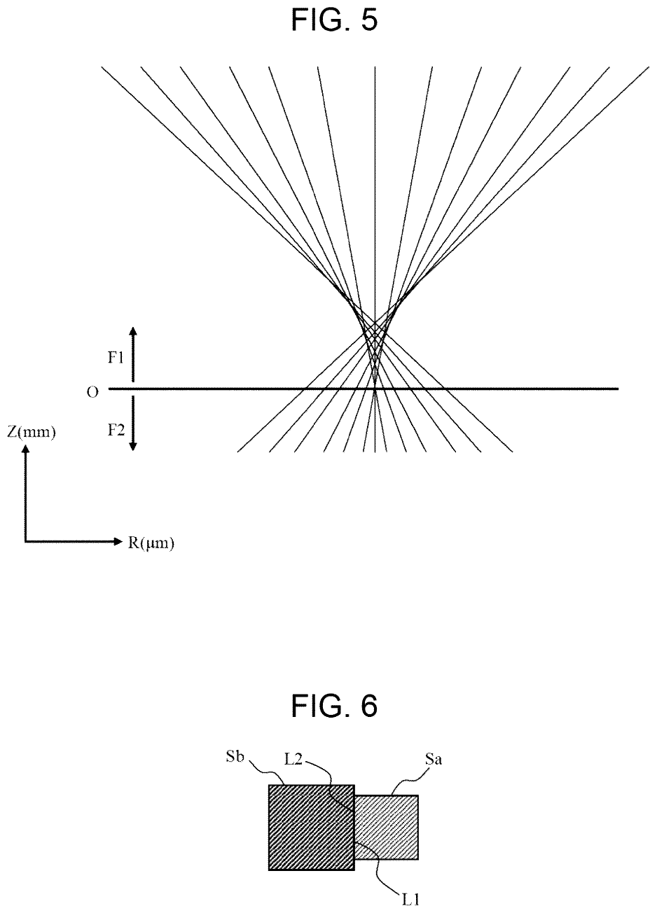

Referring to FIG. 5, with respect to an image plane O, an F1 side is an under-focal point, and an F2 side is a hyperfocal point. The same position is designated as the beam irradiation position under a condition of each of the hyperfocal point and the under-focal point in a state where the optical condition of the focal point coincides with the position of the stage 109. For example, when the beam irradiation position is designated in the state of the image plane O in FIG. 5, scheduled irradiation positions coincide with each other even if the beam is emitted at the hyperfocal point and the under-focal point. However, it is not necessary to designate an irradiation position at the position of the image plane O, and any condition may be used as long as the irradiation position is designated in a state where the optical condition and the position of the stage 109 are the same. As for the method of setting the defocusing and the irradiation time, for example, in the case of a condition of an acceleration voltage of 30 kV, when the voltage of the objective lens electrode 107 is changed around ±100 V from the condition of the focal point, a defocused beam can be formed, and an irradiation mark with which an irradiation mark can be checked can be formed by performing irradiation for several seconds to several tens of seconds. As the order of the beam irradiation, a hyperfocal beam may be first, or an under-focal beam may be first. In Embodiment 1, the voltage of the objective lens electrode 107 is changed to change the focal position. Alternatively, the voltage of the focusing lens electrode 103 may be changed to change the focal position. As the sample 1 irradiated with the ion beam, a standard sample dedicated to irradiation may be used, or a sample used for processing may be irradiated with the ion beam, as long as the sample is a material on which an irradiation mark can be formed.

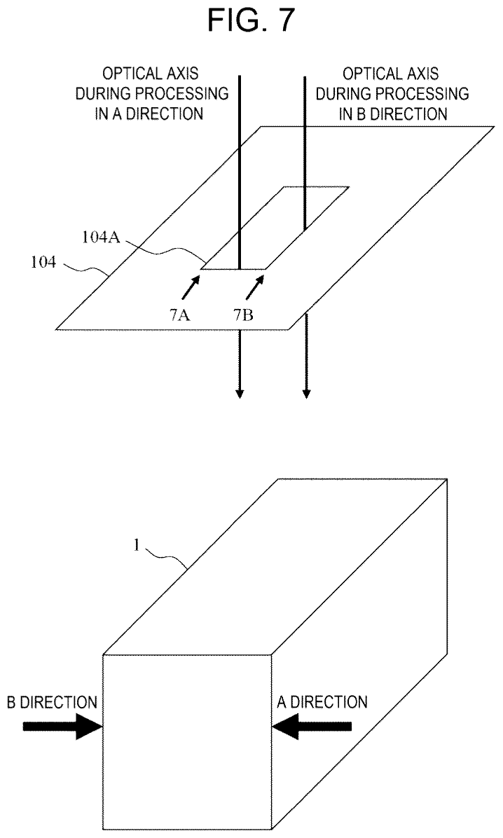

Eighthly, the control unit 113 displays the irradiation mark on the display unit 111 (step S208). In the example of FIG. 6, a center of a side L1 (first side) corresponding to the linear edge E of the aperture 104A of an irradiation mark Sa formed by the ion beam having the first focal point coincides with a center of a side L2 (second side) corresponding to the linear edge E of the aperture 104A of an irradiation mark Sb formed by the ion beam having the second focal point. When the center of the side L1 coincides with the center of the side L2, the linear edge E of the aperture 104A of the movable diaphragm 104 is perpendicular to the optical axis of the ion beam. In order to observe the irradiation mark, the irradiation mark may be irradiated with the ion beam under an optical condition in which the irradiation mark is formed, or the irradiation mark may be irradiated with the ion beam under an optical condition different from the optical condition in which the irradiation mark is formed. Further, when the ion beam device 100 is a complex machine including the SEM column 117 and the ion beam column 108, the SEM column 117 may be used to observe the irradiation mark.

Ninthly, the control unit 113 adjusts the position of the aperture 104A of the movable diaphragm 104 based on a positional relation between the center of the side L1 and the center of the side L2 (step S209). The control unit 113 adjusts the position of the aperture 104A of the movable diaphragm 104 so that the center of the side L2 of the irradiation mark Sa coincides with the center of the side L3 of the irradiation mark Sb. As shown in FIG. 6, when the center of the side L1 of the irradiation mark Sa and the center of the side L2 of the irradiation mark Sb coincide with each other, the control unit 113 adjusts the position of the movable diaphragm 104 to a position when the irradiation marks Sa and Sb are formed.

When the center of the side L1 of the irradiation mark Sa and the center of the side L2 of the irradiation mark Sb do not coincide with each other, the control unit 113 may calculate a position of the movable diaphragm based on a distance between the center of the side L1 of the irradiation mark Sa and the center of the side L2 of the irradiation mark Sb, the movement amount of the movable diaphragm 104 in the movement direction of the aperture 104A, the focal position, and the like.

After adjusting the position of the aperture 104A of the movable diaphragm 104, the control unit 113 performs processing of the sample 1 using the ion beam that has passed through the aperture 104A of the movable diaphragm 104 disposed at an adjusted position. As the optical condition used for the processing of the sample 1, it is necessary to use a defocusing condition.

When the influence of the aberration is large, a sharp-edged beam cannot be formed due to the influence of the aberration even when the optical axis and the edge of the aperture 104A are perpendicular to each other at the focusing point having the minimum diameter. This can be said in the case of reflecting the influence of either spherical aberration or chromatic aberration, and in the case of such a condition, edge-sharpening processing can be performed on the processing surface by performing processing by moving the focal position to the defocus side, particularly to the under-focal point side, more than the amount of aberration. When the influence of the Gaussian image of the ion source is large although the influence of the aberration is small, that is, when the light source is largely projected onto a sample surface, it is necessary to use the defocusing.

$$d = 2 \sqrt{{( M \cdot \frac{ρ}{2} )}^{2} + {( \frac{1}{4} {C}_{S} \cdot {α}^{3} )}^{2} + {( \frac{1}{2} {C}_{C} \cdot α \cdot \frac{Δ V}{V} )}^{2}} \qquad [ Math . 1 ]$$

The above formula 1 is expressed by a diameter (d) of an ion beam focused on the sample, the optical system magnification M, the light source diameter ρ, the spherical aberration coefficient Cs, the chromatic aberration coefficient Cc, the beam half angle α, the energy width ΔV of the emitted particles, and the beam energy V. As shown in the above formula 1, when α is set to 0, the first term, that is, the Gaussian image remains as the beam diameter. For example, p has a size of 50 nm in the case of a Ga liquid ion source, and therefore, a beam width at a focal point is several nanometers to several tens of nanometers.

The profile of the beam spot reflects an intensity distribution of the light source and does not have an edge.

Therefore, even in the case of such a condition, it is possible to perform edge-sharpening processing without being affected by the intensity distribution of the light source by using the defocusing condition. Although the defocusing amount needs to be several tens of micrometers, the defocusing amount can be reduced by reducing the optical system magnification M.

In the setting of a processing region, even when the defocusing is used, the processing position shift does not occur by performing the above optical adjustment method. That is, the side where the optical axis and the linear edge of the aperture 104A coincide with each other may be set as a processing frame along a surface to be processed.

Further, under the condition that processing is performed from a plurality of directions, it is not necessary to have a plurality of apertures 104A when the aperture 104A having two or more linear edges is used.

For example, in the preparation of a TEM sample as shown in FIG. 7, a thin-piece sample is prepared by processing a sample piece (sample 1) from two directions, an A direction and a B direction. The sample 1 is processed using a rectangular aperture 104A having two sides, linear edges 7A (first linear edge) and 7B (second linear edge) to prepare a thin-piece sample. Specifically, the sample 1 is processed from the A direction with an ion beam having an optical axis perpendicular to the linear edge 7A, and the sample 1 is processed from the B direction with an ion beam having an optical axis perpendicular to the linear edge 7B.

Each processing in the flowchart of FIG. 3 described above is executed for each of the linear edges 7A and 7B, and a position of the aperture 104A satisfying a condition that the linear edge 7A and the optical axis of the ion beam are perpendicular to each other and a position of the aperture 104A satisfying a condition that the linear edge 7B and the optical axis of the ion beam are perpendicular to each other are registered. Specifically, the control unit 113 registers, based on a positional relation between the first side corresponding to the linear edge 7A of the irradiation mark formed by the hyper-focused ion beam and the second side corresponding to the linear edge 7A of the irradiation mark formed by the under-focal point ion beam, a first position of the aperture 104A of the movable diaphragm 104 to be used in the processing using the linear edge 7A. In addition, the control unit 113 registers, based on a positional relation between a third side corresponding to the linear edge 7B of the irradiation mark formed by the hyper-focused ion beam and a fourth side corresponding to the linear edge 7B of the irradiation mark formed by the under-focused ion beam, a second position of the aperture 104A of the movable diaphragm 104 to be used in the processing using the linear edge 7B.

During the processing of the sample 1 in each direction, registered position information of each aperture 104A is called, the aperture 104A is moved, and the sample 1 is processed in each direction. As described above, even when the number of apertures 104A is one, processing under two conditions can be performed by using the plurality of linear edges 7A and the plurality of linear edges 7B. That is, if the position of the aperture 104A is registered for each of the linear edges 7A and 7B of the aperture 104A, the sample 1 can be processed in each direction with only one aperture 104A without having a plurality of apertures 104A.

Here, an example of processing the sample from two directions for preparing the TEM sample has been described. However, if it is necessary to process the sample from a plurality of directions, the positions of the plurality of apertures 104A may be registered for the linear edges of the apertures 104A in the plurality of directions. Further, different apertures may be used for the respective processing directions.

During the processing, as a method of matching the directions of the sample 1 and the linear edge of the aperture 104A, the direction of the aperture 104A is determined based on the spot irradiation mark acquired by defocusing, and the position of the aperture 104A of the movable diaphragm 104 may be changed or the sample may be rotated by using the movable diaphragm 104 provided with a mechanism capable of rotating not only along the X axis and the Y axis but also in a state of being parallel to X and Y planes so as to match a direction of a sample surface to be processed.

### (Effects of Embodiment 1)

In Embodiment 1, the linear edge E of the aperture 104A of the movable diaphragm 104 and the optical axis of the ion beam can be perpendicular to each other by adjusting the position of the aperture 104A of the movable diaphragm 104 based on the positional relation between the side L1 of the irradiation mark Sa and the side L2 of the irradiation mark Sb on the sample 1. Accordingly, the component of the ion beam having the peak intensity passes through the linear edge E, and therefore, sagging of the edge of the sample can be reduced.

In Embodiment 1, the movement amount of the movable diaphragm 104 in the predetermined direction is smaller than the aperture width of the aperture 104A of the movable diaphragm 104 in the predetermined direction. Accordingly, the linear edge of the aperture 104A of the movable diaphragm 104 can be prevented from moving beyond the optical axis of the ion beam.

In Embodiment 1, by using the hyper-focused ion beam and the under-focused ion beam, the irradiation mark of the sample can be prevented from being formed at the same position. Accordingly, the irradiation mark can be easily checked.

### Embodiment 2

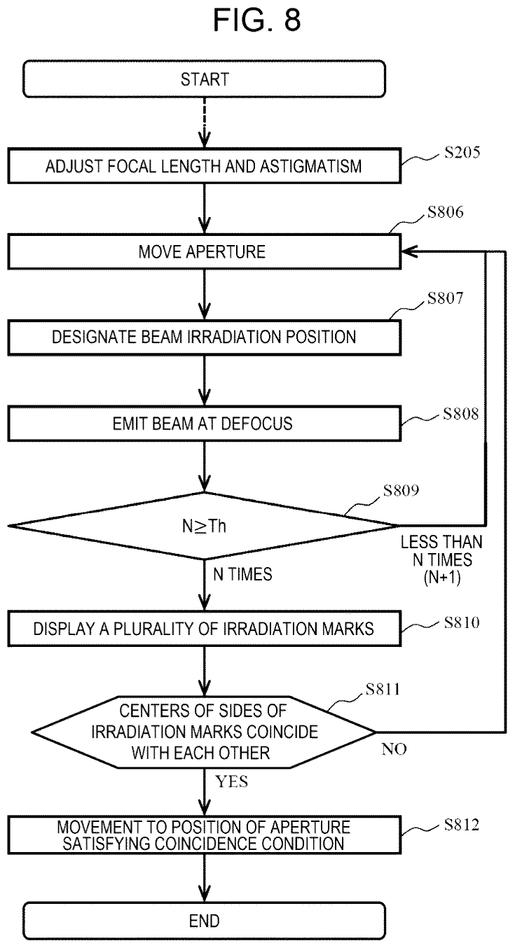

Next, Embodiment 2 will be described with reference to FIGS. 8, 9, and 10. The steps up to the step of adjusting the focal length and the astigmatism and adjusting the shape of the beam (step S205) are the same as those in the adjustment method of Embodiment 1, and therefore, they are omitted in FIG. 8, and the repeated description thereof will be omitted. FIG. 8 is a flowchart illustrating an optical axis adjustment method according to Embodiment 2.

After adjusting the focal length and the astigmatism, the control unit 113 moves the aperture 104A of the movable diaphragm 104 to the first position (step S806). First, the movable diaphragm 104 may not be moved, and the movable diaphragm 104 may be stopped at the position of the movable diaphragm 104 used in the adjustment in step S205.

Next, the control unit 113 designates a beam irradiation position (step S807), and performs irradiation with a defocused beam having a defocusing amount larger than the aberration (step S808). The processing in step S808 is the same as that in step S207 in Embodiment 1. The irradiation position of the ion beam on the X-Y plane is any position on an angle of view.

Then, the control unit 113 determines whether to move the aperture 104A of the movable diaphragm 104 to the second position. Specifically, the control unit 113 determines whether the number of times of movements N of the movable diaphragm 104 is equal to or greater than the threshold Th (step S809).

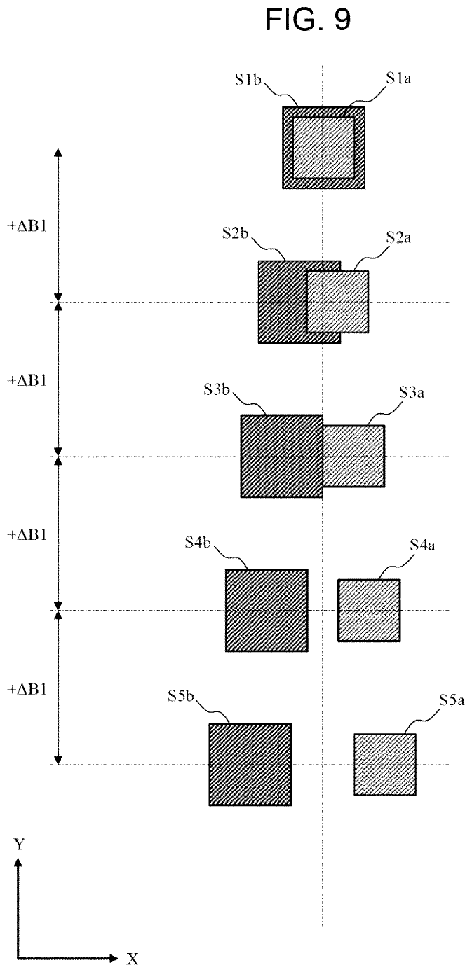

When the number of times of movements N of the aperture 104A is less than the designated number of times (threshold Th) (step S809: less than N times), the control unit 113 moves the aperture 104A of the movable diaphragm 104 (step S806), sets the beam irradiation position again (step S807), and performs beam irradiation at a reset position (step S808). At this time, the number of times of movements N is incremented by 1. The movement amount of the aperture 104A in the movement direction is in a range in which the movement amount is smaller than the aperture width of the aperture 104A in the movement direction. The designation of the second and subsequent beam irradiation positions on the X-Y plane uses a method of applying a voltage to the deflector 106 that scans a sample with the ion beam and deflecting a passing ion beam by a predetermined amount (indicated by ΔB1 in FIG. 9) in the X direction and the Y direction. Here, the flow in which the voltage is applied to the deflector 106 to change the beam irradiation position after the aperture 104A of the movable diaphragm 104 is moved has been described. However, the movement of the movable diaphragm 104 and the application of the voltage to the deflector 106 may be performed simultaneously, or the application of the voltage may be performed first. The control unit 113 stores the movement amount of the aperture 104A of the movable diaphragm 104 and the irradiation position or the change amount of a beam.

After repeating the movement of the aperture 104A and the defocused beam irradiation by the designated number of times (threshold Th) (step S809: N times), the control unit 113 displays images of a plurality of irradiation marks on the display unit 111 (step S810). The control unit 113 selects an irradiation mark set in which centers of the sides corresponding to the linear edge E of the aperture 104A coincide with each other from a plurality of irradiation mark sets including a first irradiation mark formed by an ion beam having the first focal point and a second irradiation mark formed by an ion beam having the second focal point (step S811: Yes). The control unit 113 moves the aperture 104A of the movable diaphragm 104 to a position satisfying the condition in which the centers of the sides corresponding to the linear edge E coincide with each other. Specifically, the control unit 113 calculates the movement amount of the aperture 104A of the movable diaphragm 104 based on the stored beam irradiation position or displacement amount, and moves the position of the aperture 104A of the movable diaphragm 104 (step S812).

However, in the determination in step S811, there is also a case where an irradiation mark set in which the centers of the sides coincide with each other is not present. In that case (step S811: No), an irradiation mark set in which a distance between the centers of the sides is closest is selected, and this state is set as a starting point. In the example of FIG. 9, when the irradiation marks overlap each other, for example, the state of S2 is a state where the accumulated movement amount increases due to the insufficient movement amount, and when the irradiation marks do not overlap each other, for example, the states of S4 and S5 are a state in which the accumulated movement amount decreases due to the excessive movement amount, and the processing is repeated from step S806. The magnitude of the movement amount is appropriately adjusted such that the centers of the irradiation marks on one side are closest to each other. When there is no irradiation mark set in which the centers of the sides coincide with each other (step S811: No), the irradiation mark set in which the distance between the centers of the sides is closest may be selected, and the position of the aperture 104A of the movable diaphragm 104 may be moved according to a calculation formula based on a positional relation of the sides of the irradiation marks of the irradiation mark set.

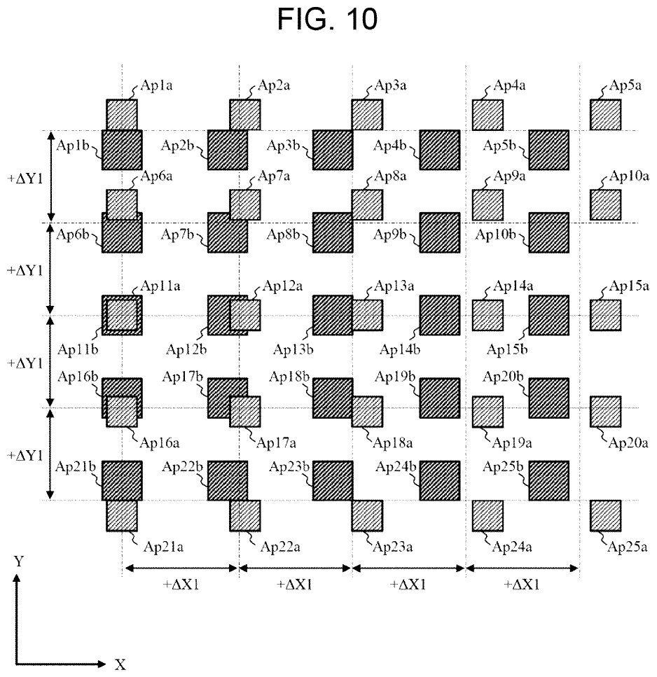

FIGS. 9 and 10 are diagrams showing an example of the irradiation mark. In the case of FIG. 9, the position of the aperture 104A of the movable diaphragm 104 is changed only in one of the X direction and the Y direction, and the irradiation mark is formed along the Y axis. For example, when the sample 1 is irradiated with the ion beam at the position of the aperture 104A of the movable diaphragm 104 used in step S205, the irradiation marks S1a and S1b are formed. When the second irradiation is performed at a position where the irradiation position of the ion beam is deflected by ΔB1, irradiation marks S2a and S2b are formed. The irradiation is repeated until the irradiation marks S5a and S5b are formed. In the example of FIG. 9, a center of one side of the irradiation mark S3a at the third irradiation coincides with a center of one side of the irradiation mark S3b, and therefore, the linear edge E of the aperture 104A when the irradiation marks S3a and S3b are formed is perpendicular to the optical axis of the ion beam.

In the case of FIG. 10, the position of the aperture 104A of the movable diaphragm 104 is changed in both the X direction and the Y direction, and the irradiation position of the ion beam is also changed in the X direction and the Y direction according to the movement direction of the aperture 104A of the movable diaphragm 104. The beam is deflected by ΔX1 in the X direction and by ΔY1 in the Y direction, and emitted to the sample 1. In FIG. 10, one side of an irradiation mark Ap13a and one side of an irradiation mark Ap13b of an irradiation mark set (irradiation mark set at the center in the drawing) which is formed at the third irradiation overlap each other and a center of one side of the irradiation mark Ap13a and a center of one side of the irradiation mark Ap13b coincide with each other, and therefore, the linear edge E of the aperture 104A when the irradiation marks Ap13a and Ap13b are formed is perpendicular to the optical axis of the ion beam.

However, the irradiation marks in FIGS. 9 and 10 are merely examples, and the movement direction of the aperture 104A of the movable diaphragm 104 can be adjusted according to the direction of the linear edge E of the aperture 104A. The irradiation marks do not need to be along the X axis or the Y axis, and the number of irradiation marks is not limited. Further, although the ion beams are deflected to have the same width of the deflection amount in the above example, the widths of the deflection amount may be different.

### (Effects of Embodiment 2)

In Embodiment 2, the sample is irradiated with the ion beam having the first focal point and the ion beam having the second focal point a plurality of times by moving the movable diaphragm 104, and the position of the aperture 104A of the movable diaphragm 104 is adjusted based on the positional relation between the sides of the irradiation mark set selected from the plurality of irradiation mark sets. Accordingly, by observing the plurality of irradiation mark sets, it is possible to easily find the condition that the linear edge E of the aperture 104A of the movable diaphragm 104 is perpendicular to the optical axis of the ion beam.

### Embodiment 3

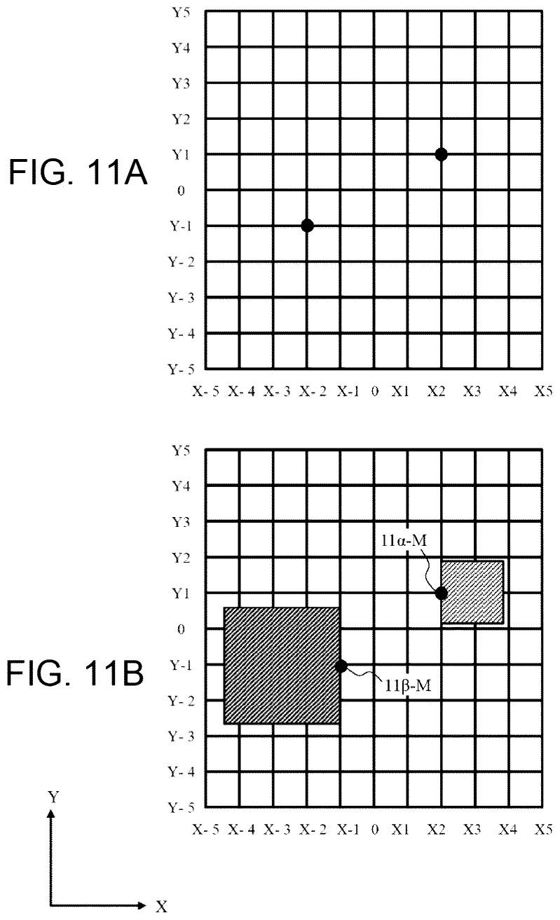

Next, Embodiment 3 will be described with reference to FIG. 11.

In Embodiment 1 and Embodiment 2, at one selected position of the aperture 104A of the movable diaphragm 104, the irradiation position of the hyper-focused ion beam and the irradiation position of the under-focused ion beam coincide with each other in a state where the optical conditions and the positions of the stage 109 are the same (step S207 and step S807). However, if the optical conditions and the positions of the stage 109 are the same, the irradiation position of the hyper-focused ion beam and the irradiation position of the under-focused ion beam may be different in the X-Y plane.

In (I) of FIG. 11, when the irradiation position of the hyper-focused ion beam is set to coordinates of (X, Y)=(X−2, Y−1) and the irradiation position of the under-focused ion beam is set to coordinates of (X, Y)=(X2, Y1), the irradiation mark in which the centers of the sides coincide with each other is not obtained as shown in (II) of FIG. 11 even if the linear edge E of the aperture 104A and the optical axis of the ion beam are perpendicular to each other. However, the position of the irradiation mark moves by the amount of the displacement of the ion beam irradiation position, and therefore, correction can be performed. In this case, it is possible to check whether the linear edge E of the aperture 104A and the optical axis of the ion beam are perpendicular to each other by checking whether a distance between the center portions (11α-M and 11β-M) of the opposing sides of the irradiation mark coincides with the distance corresponding to the amount of displacement of the irradiation position of the ion beam.

### Embodiment 4

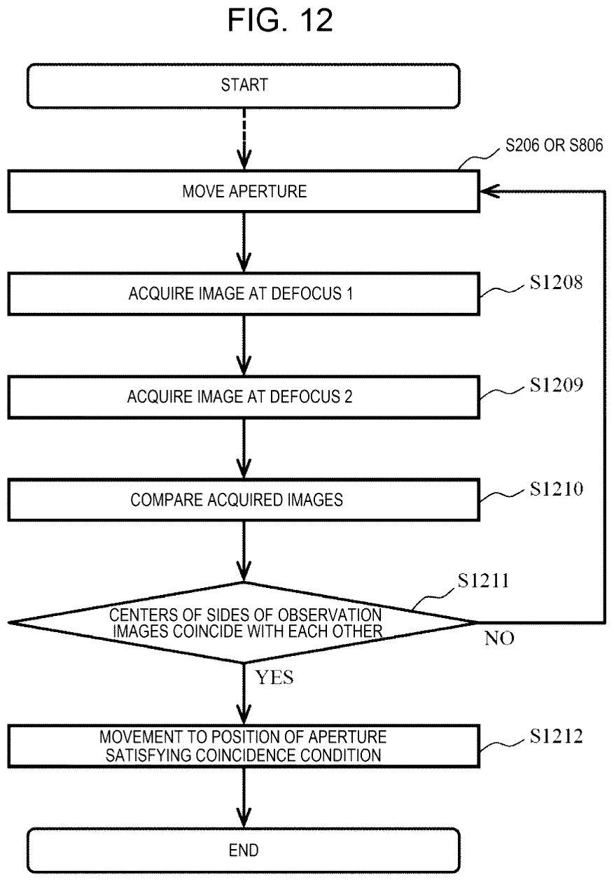

Next, Embodiment 4 will be described with reference to FIGS. 12 to 15. The irradiation with the ion beam is spot irradiation in Embodiments 1 to 3 described above, and may be scanning irradiation.

FIG. 12 is a flowchart illustrating an ion beam adjustment method according to Embodiment 4. The steps up to the step of moving the aperture 104A to any position (step S206 or S806) are the same as those in Embodiments 1 to 3 described above, and therefore, repeated description thereof is omitted.

After the movement of the aperture 104A, the control unit 113 acquires an image at either a hyperfocal point or an under-focal point (step S1208). Conditions of the hyperfocal point or the under-focal point are the same as those in Embodiment 1. During image acquisition, an observation target having one or more edges needs to be present within an angle of view to be acquired. Further, the position of the target is moved so that the side where the edge of the observation target is present serves as a comparison target surface. As the observation target, for example, a processing mark processed into a square may be used.

Next, the control unit 113 acquires an image again at a defocus that is not used in step S1208, that is, at an under-focal point when an image is acquired at a hyperfocal point in step S1208, and at a hyperfocal point when an image is acquired at an under-focal point in step S1208 (step S1209). At this time, an image in the same range, which has the same angle of view as the angle of view acquired in step S1208, is acquired.

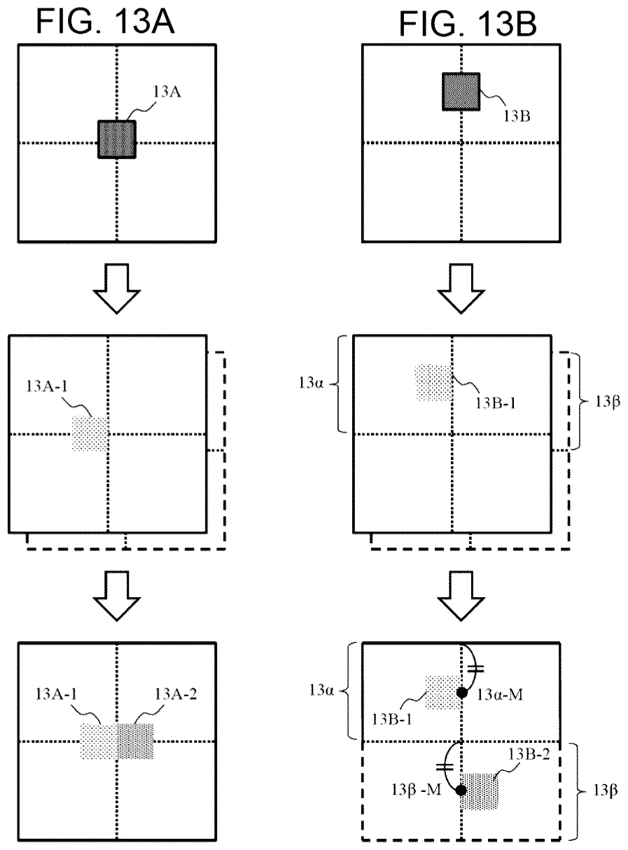

Then, the control unit 113 compares the image acquired in step S1208 with the image acquired in step S1209 (step S1210). As the comparison method, for example, as shown in (A) of FIG. 13, an observation image 13A-1 of an observation target 13A acquired at the first focal point and an observation image 13A-2 of the observation target 13A acquired at the second focal point may be superimposed and displayed, or as shown in (B) of FIG. 13, an image 13a including an observation image 13B-1 of an observation target 13B acquired at the first focal point and an image 13ß including an observation image 13B-2 of the observation target 13B acquired at the second focal point may be displayed in half. The observation image in Embodiment 4 is an example of an irradiation mark of the present disclosure.

Thereafter, the control unit 113 checks, based on the comparison image, whether a center of a side in the observation image 13A-1 corresponding to an edge of the observation target 13A and a center of a side in the observation image 13A-2 corresponding to an edge of the observation target 13A coincide with each other (step S1211). However, as shown in (B) of FIG. 13, when the images 13 and 13ß are displayed in half, the side of the observation image 13B-1 and the side of an observation image 13B-2 corresponding to an edge of the observation target 13B may not be displayed in a manner of facing each other. In this case, it is necessary to check whether both sides overlap on the same axis or whether the centers of the sides (the positions of 13a-M and 13B-M in FIG. 13) are present at specific locations, for example, positions at the same distance from the upper end of the image. Here, as shown in (B) of FIG. 13, the images are displayed in the upper and lower halves, and the images may be displayed in the left and right halves. In the case of displaying and checking half by half, the linear edge cannot be checked depending on the position of the observation target, and therefore, the display method is changed according to the observation target.

When the centers of the sides of the observation images do not coincide with each other (step S1211: No), the control unit 113 repeats the processing from step S206 or S806 again to perform fine adjustment of the aperture 104A. When the centers of the sides of the observation images coincide with each other (step S1211: Yes), the control unit 113 moves the aperture 104A of the movable diaphragm 104 to a position satisfying a condition in which the centers of the sides of the observation images coincide with each other (step S812).

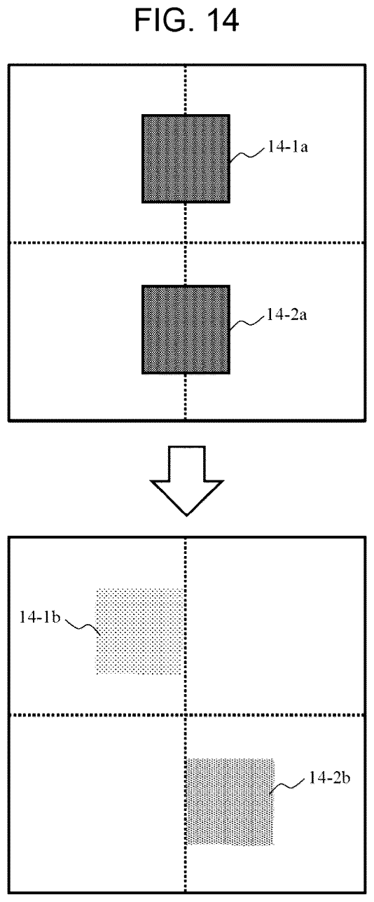

Although a case where only one observation target including an edge is present has been described above, two or more observation targets may be present. For example, as shown in FIG. 14, when two observation targets, i.e., observation targets 14-1a and 14-2a are present at one angle of view, an image may be acquired at a hyperfocal point (or an under-focal point) in the upper half and acquired at an under-focal point (or a hyperfocal point when the upper half is an under-focal point) in the lower half. It may be found that the sides of the observation images 14-1b and 14-2b after the image acquisition coincide with or correspond to each other. In this case, the comparison can be performed without correcting the sizes of the observation targets by aligning the sizes of the observation targets.

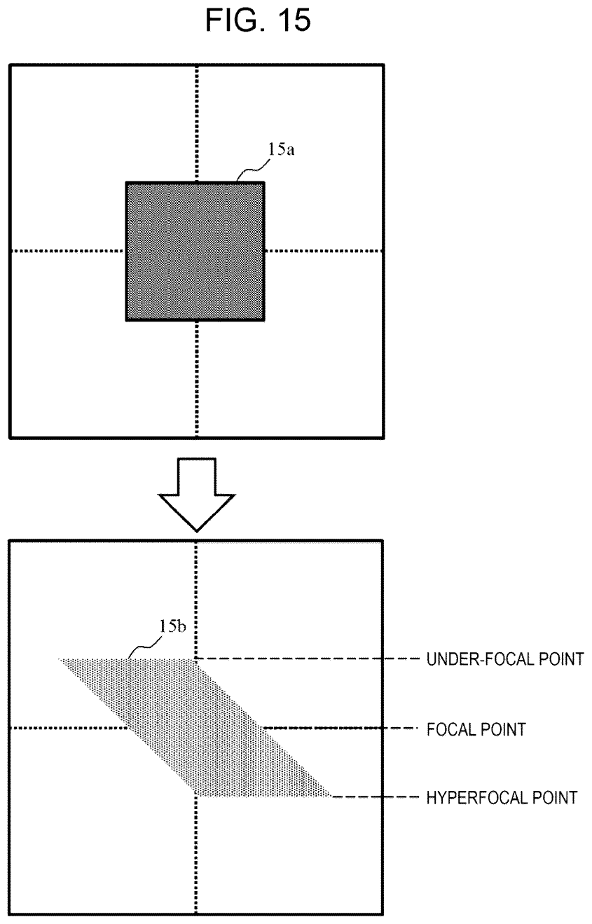

Further, as shown in FIG. 15, one image may be acquired while changing the focal position with respect to one observation target 15a. In this case, the ion beam needs to be in a target defocused state at a position approaching the observation target 15a, and the focal position needs to be changed stepwise until the observation target 15a is reached and the other defocus state is reached. A shape of the observation target 15a needs to have two edges in a vertical direction perpendicular to a scanning direction. Further, the observation target 15a needs to be present at a location where a center position of the observation target 15a and a center of the angle of view coincide with each other. For example, if the observation target 15a has a quadrangular shape, when the linear edge of the aperture 104A and the optical axis of the ion beam are perpendicular to each other, the acquired image has a shape such as a parallelogram as in an observation image 15b, and has a shape in which the diagonals are on the same axis, and the center position of the observation target 15a is not shifted from the center position of the angle of view.

### (Effects of Embodiment 4)

In Embodiments 1 to 3, the irradiation marks have been formed on the sample. However, in Embodiment 4, the linear edge of the aperture 104A of the movable diaphragm 104 and the optical axis of the ion beam can be perpendicular to each other based on the observation image without forming the irradiation mark on the sample.

### <Modification>

The invention is not limited to the above-described embodiments and includes various modifications. For example, the above-described embodiments have been described in detail to facilitate understanding of the invention, and the invention is not necessarily limited to those including all the configurations described above. A part of a configuration of a certain embodiment can be replaced with a configuration of another embodiment, and a configuration of another embodiment can also be added to a configuration of a certain embodiment. A part of a configuration according to each embodiment may be added, deleted, or replaced with another configuration.

The setting of the irradiation position of the ion beam and the selection of the optimum position of the aperture 104A of the movable diaphragm 104 may be performed manually or automatically.

The above embodiments have stated that the defocus is changed by changing a lens voltage of the objective lens electrode 107 or the focusing lens electrode 103, but the stage position can also be changed and adjusted. For example, the stage on which the sample is placed may be moved parallel to the optical axis of the ion beam, and the sample may be irradiated with the ion beam without changing the focal position of the ion beam at two positions sandwiching an imaging position.

In the adjustment of the optical axis of the ion beam described above, the adjustment method in the two-stage lens system is described, but the adjustment method is the same in the multi-stage lens system.

In the above-described embodiment, although the sample 1 is irradiated with the hyper-focused ion beam and the under-focused ion beam, the sample may be irradiated with ion beams having two different hyperfocal points, or may be irradiated with ion beams having two different under-focal points.

### REFERENCE SIGNS LIST

100: ion beam device
101: ion source
102: extraction electrode
103: focusing lens electrode
104: movable diaphragm
104A: aperture
105: Aligner and Stigma electrode
106: deflector
107: objective lens electrode
108: ion beam column
109: stage
110: secondary particle detector
111: display unit
112: vacuum chamber
113: control unit
117: SEM column
150: processor
151: main storage unit
152: auxiliary storage unit
153: input and output I/F
E, 7A, 7B: linear edge
F1: under-focal point
F2: hyperfocal point
S1a to S5b, Ap1a to Ap25b: irradiation mark
11α-M, 11β-M: center of side of irradiation mark
13A, 13B, 14-1a, 14-2a, 15a: observation target
13A-1, 13A-2, 13B-1, 13B-2, 14-1b, 14-2b, 15b: observation image
13α, 13β: image
13α-M, 13β-M: center of side of check image
1: sample

1. An ion beam adjustment method, which is a method for adjusting an ion beam emitted to a sample via a movable diaphragm having an aperture with at least one linear edge, the method comprising:
irradiating the sample with an ion beam having a first focal point and an ion beam having a second focal point different from the first focal point; and
adjusting a position of the aperture of the movable diaphragm based on a positional relation between a first side corresponding to the linear edge of a first irradiation mark formed by the ion beam having the first focal point and a second side corresponding to the linear edge of a second irradiation mark formed by the ion beam having the second focal point.

2. The ion beam adjustment method according to claim 1, wherein
the sample is irradiated with the ion beam having the first focal point and the ion beam having the second focal point a plurality of times by moving the movable diaphragm, and
adjusting the position of the aperture of the movable diaphragm includes selecting, from a plurality of irradiation mark sets including the first irradiation mark and the second irradiation mark formed on the sample, the irradiation mark set in which a distance between the first side and the second side is closest, and adjusting the position of the aperture of the movable diaphragm based on a positional relation between the first side and the second side in the selected irradiation mark set.

3. The ion beam adjustment method according to claim 2, wherein
a movement amount of the movable diaphragm in a predetermined direction is smaller than an aperture width of the aperture of the movable diaphragm in the predetermined direction.

4. The ion beam adjustment method according to claim 1, wherein
adjusting the position of the aperture of the movable diaphragm includes adjusting the position of the aperture of the movable diaphragm based on a positional relation between a center of the first side and a center of the second side.

5. The ion beam adjustment method according to claim 1, wherein
adjusting the position of the aperture of the movable diaphragm includes adjusting the position of the aperture of the movable diaphragm such that the first side and the second side overlap each other and a center of the first side and a center of the second side coincide with each other.

6. The ion beam adjustment method according to claim 1, wherein
the first focal point is a hyperfocal point, and the second focal point is an under-focal point.

7. The ion beam adjustment method according to claim 1, wherein
irradiating the sample with the ion beam having the first focal point or the ion beam having the second focal point includes moving a stage on which the sample is placed in parallel to an optical axis of the ion beam and irradiating the sample with the ion beam having the first focal point or the ion beam having the second focal point at two positions sandwiching an imaging position without changing a focal position of the ion beam.

8. The ion beam adjustment method according to claim 1, wherein
irradiating the sample with the ion beam having the first focal point and the ion beam having the second focal point includes changing a focal position of the ion beam by changing a voltage applied to a focusing lens electrode, an objective lens electrode, or both the focusing lens electrode and the objective lens electrode, and irradiating the sample with the ion beam having the first focal point and the ion beam having the second focal point.

9. The ion beam adjustment method according to claim 1, wherein
irradiation with the ion beam is spot irradiation or scanning irradiation.

10. The ion beam adjustment method according to claim 1, wherein
the aperture is an aperture having at least a first linear edge and a second linear edge,
the method further comprising:
registering, based on a positional relation between a first side corresponding to the first linear edge of the first irradiation mark and a second side corresponding to the first linear edge of the second irradiation mark, a first position of the aperture of the movable diaphragm to be used in processing using the first linear edge; and
registering, based on a positional relation between a third side corresponding to the second linear edge of the first irradiation mark and a fourth side corresponding to the second linear edge of the second irradiation mark, a second position of the aperture of the movable diaphragm to be used in processing using the second linear edge.

11. An ion beam device comprising:
an ion source;
an optical system including a movable diaphragm through which an ion beam emitted from the ion source passes and having an aperture with at least one linear edge, and configured to irradiate a sample with the ion beam;
a stage on which the sample is to be placed; and
a control unit configured to control the optical system or the stage to irradiate the sample with an ion beam having a first focal point and an ion beam having a second focal point different from the first focal point, wherein
the control unit adjusts a position of the aperture of the movable diaphragm based on a positional relation between a first side corresponding to the linear edge of a first irradiation mark formed by the ion beam having the first focal point and a second side corresponding to the linear edge of a second irradiation mark formed by the ion beam having the second focal point.

12. The ion beam device according to claim 11, wherein
the control unit is configured to
move the movable diaphragm a plurality of times to irradiate the sample with the ion beam having the first focal point and the ion beam having the second focal point,
select, from a plurality of irradiation mark sets including the first irradiation mark and the second irradiation mark formed on the sample, the irradiation mark set in which a distance between the first side and the second side is closest, and
adjust the position of the aperture of the movable diaphragm based on a positional relation between the first side and the second side in the selected irradiation mark set.

13. The ion beam device according to claim 12, wherein
a movement amount of the movable diaphragm in a predetermined direction is smaller than an aperture width of the aperture of the movable diaphragm in the predetermined direction.

14. The ion beam device according to claim 11, wherein
the control unit adjusts the position of the aperture of the movable diaphragm based on a positional relation between a center of the first side and a center of the second side.

15. The ion beam device according to claim 11, wherein
the control unit adjusts the position of the aperture of the movable diaphragm such that the first side and the second side overlap each other and a center of the first side and a center of the second side coincide with each other.

16. The ion beam device according to claim 11, wherein
the first focal point is a hyperfocal point, and the second focal point is an under-focal point.

17. The ion beam device according to claim 11, wherein
the control unit moves the stage in parallel to an optical axis of the ion beam and irradiates the sample with the ion beam having the first focal point or the ion beam having the second focal point at two positions sandwiching an imaging position without changing a focal position of the ion beam.

18. The ion beam device according to claim 11, wherein
the control unit changes a focal position of the ion beam by changing a voltage applied to a focusing lens electrode, an objective lens electrode, or both the focusing lens electrode and the objective lens electrode of the optical system, and irradiates the sample with the ion beam having the first focal point and the ion beam having the second focal point.

19. The ion beam device according to claim 11, wherein
irradiation with the ion beam is spot irradiation or scanning irradiation.

20. The ion beam device according to claim 11, wherein
the aperture is an aperture having at least a first linear edge and a second linear edge, and
the control unit is configured to
register, based on a positional relation between a first side corresponding to the first linear edge of the first irradiation mark and a second side corresponding to the first linear edge of the second irradiation mark, a first position of the aperture of the movable diaphragm to be used in processing using the first linear edge; and
register, based on a positional relation between a third side corresponding to the second linear edge of the first irradiation mark and a fourth side corresponding to the second linear edge of the second irradiation mark, a second position of the aperture of the movable diaphragm to be used in processing using the second linear edge.
